(19) United States
(12) Patent Application Publication
(10) Pub. No.: US 2025/0308883 A1
(43) Pub. Date: Oct. 2, 2025

(54) INTEGRATING NITRIDE STRESS COMPENSATION LAYERS FOR THICK OXIDE WAFER CREATION

(71) Applicant: Tokyo Electron Limited, Tokyo (JP)

(72) Inventor: Joshua BAILLARGEON, Albany, NY (US)

(73) Assignee: Tokyo Electron Limited, Tokyo (JP)

(21) Appl. No.: 18/618,354

(22) Filed: Mar. 27, 2024

(51) Int. Cl. H01L 21/02

(52) U.S. Cl. CPC H01L 21/0217; H01L 21/02255; H01L 21/0228; H01L 21/02617

(57) ABSTRACT

Aspects of the present disclosure provide a method for creating a product wafer having an oxide layer with a thickness of greater than or equal to 10 μm. The method includes forming a thermal oxide layer on a first surface and a second surface of a semiconductor wafer. A tensile nitride layer is formed on the first surface of the semiconductor wafer and a first oxide layer is formed on top of the tensile nitride layer. A compressive nitride layer is formed on the second surface of the wafer and a second oxide layer is formed on top of the first oxide layer. A sum of a thickness of the first oxide layer and second oxide layer is greater than or equal to 10 μm.

### FIELD OF THE INVENTION

The present disclosure relates to semiconductor fabrication, and, more particularly, to methods for wafer stress compensation.

### BACKGROUND

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Semiconductor fabrication involves multiple varied steps and processes. One typical fabrication process is known as photolithography (also called microlithography). Photolithography uses radiation, such as ultraviolet or visible light, to generate fine patterns in a semiconductor device design. Many types of semiconductor devices, such as diodes, transistors, multi-level cells (MLC), and integrated circuits, can be constructed using semiconductor fabrication techniques including photolithography, etching, film deposition, surface cleaning, metallization, and so forth.

Exposure systems (also called exposure tools) are used to implement photolithographic techniques. An exposure system typically includes an illumination system, a reticle (also called a photomask) or spatial light modulator (SLM) for creating a circuit pattern, a projection system, and a wafer alignment stage for aligning a photosensitive resist-covered semiconductor wafer. The illumination system illuminates a region of the reticle or SLM with a (preferably) rectangular slot illumination field. The projection system projects an image of the illuminated region of the reticle pattern onto the wafer. For accurate projection, it is important to expose a pattern of light on a wafer that is relatively flat or planar.

Also, deposition of materials can result in tensile or compressive stress on a surface of a semiconductor wafer. This stress can result in wafer breakage or bowing of the wafer preventing precise photolithography processing. Therefore, the present inventors recognized that there exists a need to develop a stress compensation mechanism to prevent wafer stress when producing devices with thick dielectric layers.

### SUMMARY

Aspects of the present disclosure provide a method for creating a product wafer having an oxide layer with a thickness of greater than or equal to 10 μm. The method includes forming a thermal oxide layer on a first surface and a second surface of a semiconductor wafer, forming a tensile nitride layer on the first surface of the semiconductor wafer on top of the thermal oxide layer, forming a first oxide layer on top of the tensile nitride layer, forming a compressive nitride layer on the second surface of the semiconductor wafer on top of the thermal oxide layer, and forming a second oxide layer on top of the first oxide layer, where a sum of a thickness of the first oxide layer and second oxide layer is greater than or equal to 10 μm.

In an embodiment, the method further includes forming a protective layer on top of the first oxide layer before the forming the compressive nitride layer.

In an embodiment, the method further includes removing the protective layer on top of the first oxide layer after the forming the compressive nitride layer and before the forming the second oxide layer.

In an embodiment, the protective layer includes amorphous carbon.

In an embodiment, the protective layer includes a nitride.

In an embodiment, the protective layer has a thickness of 0.1-1 μm.

In an embodiment, the thermal oxide layer has a thickness of 10-100 nm.

In an embodiment, the sum of the thickness of the first oxide layer and second oxide layer is from 10-20 μm.

In an embodiment, the method further includes flipping the semiconductor wafer after the forming the first oxide layer to expose the second surface onto which the compressive nitride layer is formed.

In an embodiment, the method further includes flipping the semiconductor wafer after the forming the compressive nitride layer to expose the first oxide layer.

In an embodiment, a bow of the semiconductor wafer following the forming the second oxide layer is within ±250 μm.

In an embodiment, a thickness of the tensile nitride layer is chosen based on a desired thickness of the first oxide layer and the second oxide layer, where the tensile nitride layer imparts a tensile stress on the first surface of the semiconductor wafer to compensate for the desired thickness of the first oxide layer and the second oxide layer.

In an embodiment, a thickness of the tensile nitride layer is chosen by calculating a tensile stress offset of the tensile nitride layer.

In an embodiment, a thickness of the compressive nitride layer is adjusted based on a bow of the semiconductor wafer following the forming the first oxide layer and a desired thickness of the first oxide layer and the second oxide layer, where the compressive nitride layer imparts a compressive stress on the second surface of the semiconductor wafer to compensate for the desired thickness of the first oxide layer and the second oxide layer.

In an embodiment, a thickness of the compressive nitride layer is chosen by calculating a compressive stress offset of the compressive nitride layer.

In an embodiment, the tensile nitride layer has a larger thickness than the compressive nitride layer.

In an embodiment, the method is repeated by forming an additional compressive nitride layer and forming an additional oxide layer until a desired total oxide layer thickness is achieved.

In an embodiment, the tensile nitride layer and the compressive nitride layer impart a positive bow on the semiconductor wafer to offset a negative bow from the first oxide layer and the second oxide layer.

Aspects of the present disclosure provide an additional method for creating a product wafer having an oxide layer with a thickness of greater than or equal to 10 μm. The method includes forming a thermal oxide layer on a first surface and a second surface of a semiconductor wafer, forming a first nitride layer having one of a tensile stress and a compressive stress on the first surface of the semiconductor wafer, forming a first oxide layer on top of the first nitride layer, forming a second nitride layer on the second surface of the semiconductor wafer, the second nitride layer having the other of a tensile stress and a compressive stress, and forming a second oxide layer on top of the first oxide layer, where a sum of a thickness of the first oxide layer and second oxide layer is greater than or equal to 10 μm.

In an embodiment, the method further includes forming a protective layer on top of the first oxide layer before the forming the second nitride layer.

In an embodiment, the method further includes removing the protective layer on top of the first oxide layer after the forming the second nitride layer and before the forming the second oxide layer.

Note that this summary section does not specify every embodiment and/or incrementally novel aspect of the present disclosure or claimed invention. Instead, this summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1A is a perspective-view schematic of layers on a wafer having a magnified defect due to the layers;

FIG. 1B is a schematic of various types and severities of resulting wafer bow;

FIG. 2 depicts a method of producing a wafer with an oxide layer having a thickness of less than 10 μm, according to some embodiments of the present disclosure;

FIG. 3A is a depiction of a product wafer with an oxide thickness from 1-7 μm, according to some embodiments of the present disclosure;

FIG. 3B is a graph depicting a projected bow of the wafer with the oxide thickness from 1-7 μm as depicted in FIG. 3A, according to some embodiments of the present disclosure;

FIGS. 4A, 4B and 4C depict a method of producing a wafer with an oxide layer having a thickness of greater than 10 μm, according to some embodiments of the present disclosure;

FIGS. 5A and 5B depict a method of removing a protective layer, according to some embodiments of the present disclosure;

FIG. 6A is a depiction of a product wafer with an oxide thickness greater than 10 μm, according to some embodiments of the present disclosure;

FIG. 6B is a graph depicting a projected bow of a wafer at different stages in the method of making the embodiment as depicted in FIG. 6A, according to some embodiments of the present disclosure;

FIG. 7A is a depiction of a wafer with a tensile nitride layer, according to some embodiments of the present disclosure;

FIG. 7B is a graph depicting a bow of the wafer with the tensile nitride layer in FIG. 7A having various thicknesses (X μm), according to some embodiments of the present disclosure;

FIG. 8A is a depiction of a wafer with a compressive nitride layer, according to some embodiments of the present disclosure; and

FIG. 8B is a graph depicting a bow of a wafer with a compressive nitride layer in FIG. 8A having various thicknesses (X μm), according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

A functional semiconductor wafer can include the integration of 70+ individual layers that ultimately culminate in functional devices. Each level requires multiple processing steps including, but not limited to thin film deposition, lithography and etches to form the desired structures. For example, microfabrication of a semiconductor structure begins with a flat substrate or wafer. During microfabrication of the semiconductor structure, multiple processing steps are executed that can include depositing material on the wafer, removing material, implanting dopants, annealing, baking, and so forth. Different materials and structural formations thus formed can induce non-uniform wafer stresses, which result in bowing of the semiconductor structure, which in turn affects overlay and typically results in overlay errors of various magnitudes.

In some process steps, substrates are chucked to a substrate holder. However, when a starting wafer has a working surface that is convex, chucking becomes problematic. With edges contacting the substrate holder first, this creates a friction that prevents the wafer from spreading out properly and can cause distortions and overlay error. In contrast, when a wafer has a working surface with a small amount of concavity so that the center of the wafer touches the substrate holder with upturned edges, the wafer can be smoothly chucked. Accordingly, it can be desirable to have a relatively small amount of distance between the edges of the wafer and the substrate holder prior to chucking.

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

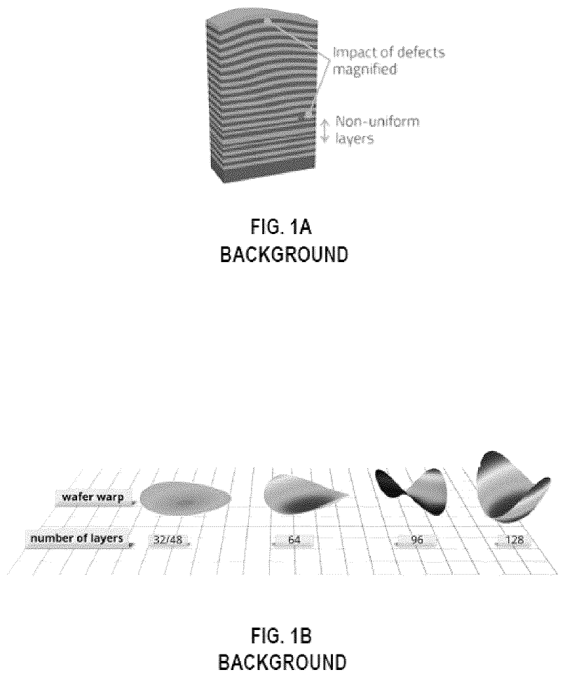

In the fabrication of 3D NAND memory devices, the device structures can extend vertically away from a working surface of a wafer. The use of larger wafers (for example, ⅚″, 100 mm, 150 mm, 200 mm, 300 mm, and 450 mm, among others) and the increasing number of layers required to fabricate state of the art integrated circuits, often results in the occurrence of significant wafer shape deformation. As 3D NAND incorporates more vertical layers, the devices also become heavier. FIG. 1A is a perspective-view schematic of layers on a wafer having a defect introduced in the lower layers. For example, 128 layers can be used for 3D NAND devices on a 300 mm wafer. As shown, a defect in an underlaying, earlier layer can be magnified to cause severe bow with later layers. FIG. 1B shows the systematic increase in the number of layers in the front side 3D NAND stack results in further wafer shape deformation and increases the severity of the problem. This can cause issues including non-uniformities, non-planarity, overlay mismatch for lithography or other processes, and wafer handling degradation. Wafer shape deformation is especially undesirable for overlay mismatch since these issues can occur early in the fabrication process and carry through subsequent steps, causing additional issues with device performance and yield.

Also, in the fabrication process of making a 3D NAND and other multi-layered devices, high aspect ratio (HAR) etching is typically used. Short loop (SL) test vehicles may be used to study the HAR etches for factory and customer support. Such a SL test vehicle should have a thick oxide layer in order to compare to the layers of a 3D NAND and other devices having many layers. However, oxide layers with a thickness of greater than 10 μm are difficult to obtain due to wafer stress and can even result in wafer breakage. There exists a need for a for a SL test vehicle with a thick oxide layer (≥10 μm) and which does not have a significant shape deformation. Minimal shape deformation allows processes such as etching and photolithography to be performed more accurately.

Aspects of the present disclosure provide methods for creating product-like surrogate wafers with a thick oxide layer for tool/process development activity that mimic complex wafer shapes/stresses of fully integrated wafers, for the sake of process development/optimization without the cost of employing actual product wafers for testing. Described herein is a method for controlling and optimizing wafer shape when having a thick oxide layer. For example, a method is proposed to manipulate wafer shape by synergistically including both a tensile nitride layer on a front surface of the wafer and a compressive nitride layer on a back surface of the wafer to compensate for stress induced by the thick oxide layer. The thickness of the tensile nitride layer and the compressive nitride layer can be varied based on the desired thickness of the overall oxide layer.

Embodiments herein include the steps of depositing a tensile nitride layer and a compressive nitride layer to mitigate bowing of a wafer having a thick oxide layer. Scanners and steppers or other photolithography tools benefit by having a relatively planar wafer, that is, a wafer without curvature and bowing. Thus, correcting any such wafer shape deformation prior to exposure of lithographic patterns means better, more accurate patterning.

The methods described herein also include reversible adjustment of the forces applied to the wafer. Accordingly, wafer shape correction herein has adaptable capability that is not present with wafer shape correction achieved through a tensile nitride layer alone, therefore a compressive nitride layer is also deposited on a backside surface of the wafer.

In an embodiment, a wafer can include a first surface and a second surface. The first surface can be a working surface and the second surface can be a backside of the wafer. In embodiments herein, the tensile nitride layer is deposited on a first surface and the compressive nitride layer is deposited on a second surface to compensate for the stress induced by a thick oxide layer which is to be deposited on the first surface.

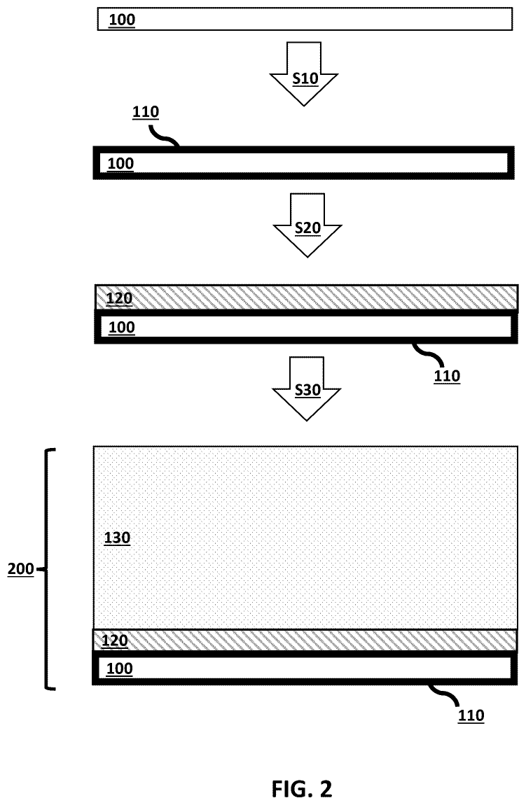

FIG. 2 depicts a method of producing a semiconductor wafer, also referred to as a wafer, with an oxide layer. In FIG. 2 the method results in a thin oxide layer, less than 10 μm. Further processing steps are required to produce a thick oxide layer while maintaining a bow within a desired range, as will be described later.

Initially the wafer (100) in step S10 undergoes thermal oxidation. Thermal oxidation is a way to produce a thin layer of oxide on the surface of the wafer (100), labeled as the thermal oxide layer (110). For example, thermal oxidation of a silicon wafer produces a layer of silicon dioxide, SiO₂, grown on the surface of a silicon wafer. The oxide layer is present on an entire surface of the wafer (100), including the first and second surface. This is because the entire wafer (100) is subjected to the thermal oxidation which typically occurs at an elevated temperature in an oxidizing atmosphere. In some embodiments, the thermal oxide layer (110) has a thickness of 10-100 nm, preferably 20-90 nm, 30-80 nm, 40-70 nm, 50-60 nm on the wafer (100). The thermal oxide layer (110) aids in adhesion of subsequent layers formed on top of the wafer (100). In a preferred embodiment, the thermal oxide layer (110) does not impart a significant shape change to the wafer (100) and does not change a bow of the wafer (100) more than ±20 μm, preferably ±15 μm, ±10 μm, or ±5 μm, relative to the initial wafer (100).

Step S20 in FIG. 2 depicts the formation of a tensile nitride layer (120) on top of the thermal oxide layer (110) on a first surface of the wafer (100). In a preferred embodiment, the nitride is silicon nitride (SiN). The tensile nitride layer (120) imparts a tensile stress on the first surface or working surface of the wafer (100). The tensile stress bows the wafer (100) up making a concave shape and a positive bow. The bow measurement is relative to a flat position of the initial wafer (100). This positive bow is to at least partially offset the layers of the oxide that are to be deposited which typically bow the wafer (100) in a negative direction.

Step S30 in FIG. 2 depicts the formation of a first oxide layer (130). The oxide layer preferably is SiO₂. Any precursor solution known in the art can be used to produce the SiO₂. In a preferred embodiment, the precursor is tetraethoxysilane (TEOS). In an embodiment, the first oxide layer (130) does not have a thickness greater than 10 μm, preferably not greater than 9 μm, 8 μm, or 7 μm. The formation of the first oxide layer (130) produces an intermediate product wafer (200). The formation of the first oxide layer (130) imparts stress on the first surface of the wafer (100) leading to a negative bow. In a preferred embodiment, the stress is not enough to cause permanent damage to the wafer (100), and therefore the layer is preferably below 10 μm. An oxide layer that has a greater thickness imparts a greater stress on the wafer (100) and can lead to breakage.

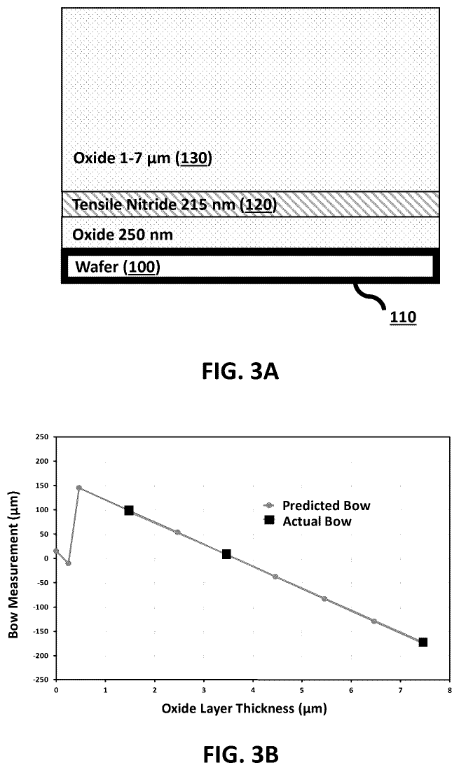

For example, FIGS. 3A-3B show how increasing a thickness of the oxide layer can induce stress on the wafer resulting in wafer deformation and a negative bow. FIG. 3A depicts oxide layers with a thickness of 1-7 μm. As shown in FIG. 3B, even with an oxide layer thickness of only 7 μm there is a significant bow of about-175 μm, which would be increased with a greater thickness of the oxide layer, as is desired in the present disclosure. This amount of bow may prevent further processes such as lithography from being accurately performed and would not be suitable as a SL test vehicle.

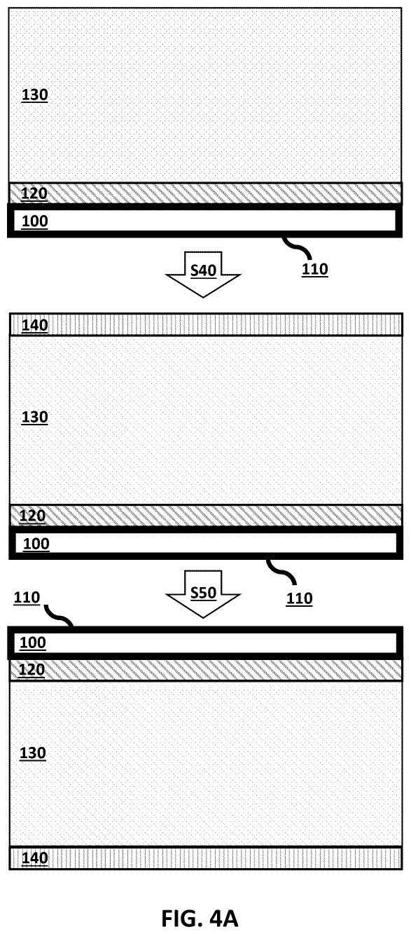

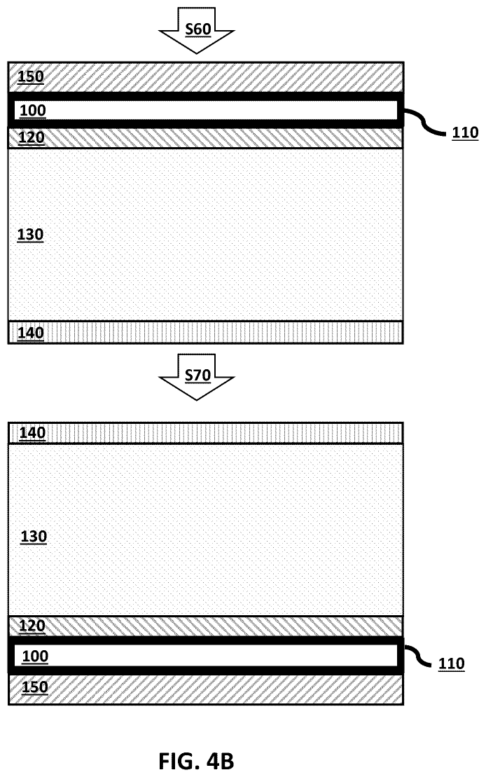

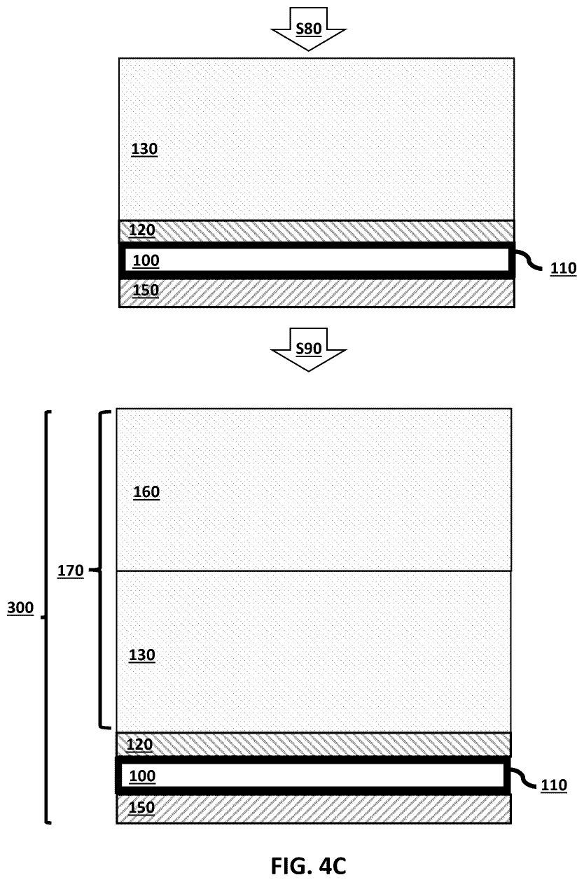

The intermediate product wafer (200) can then undergo further processing to produce a product with a thick oxide layer while maintaining a bow within a desired range. FIG. 4A depicts initial steps of a method of producing a wafer with a thick oxide layer (170) from the intermediate product wafer (200). A thick oxide layer herein is used to describe an oxide layer having a thickness of greater than 10 μm.

Depositing films on the backside of a substrate is challenging. While many different semiconductor manufacturing tools deposit films on the front side (top side or working surface) of a substrate, backside deposition is not routinely performed. With front side deposition, a substrate usually sits on a chuck, susceptor or plate and may be clamped to that surface. Such chucking can cause scratches and defects to the backside surface. The scratches and defects introduced to the backside of the substrate as a result are generally inconsequential since features and devices (transistors) are not present on the backside surface. To use existing deposition tools to deposit a film on the backside of a substrate, the substrate would have to be flipped upside down and placed on the supporting surface for processing. Chucking the substrate on the front side surface can cause scratches, introduce defects, and generally destroy features under fabrication. In view of the foregoing, it may be beneficial but not necessary, to have the protective layer (140) to prevent damage to the first oxide layer (130) during subsequent processing steps. In some embodiments, it is preferential to exclude the protective layer (140) to simplify the process because damage may be minor and only occur to the first oxide layer (130) within an acceptable range.

Step S40 in FIG. 4A depicts the formation of a protective layer (140) on top of the first oxide layer (130). The protective layer (140) can be made of amorphous carbon or a nitride. Amorphous carbon is a carbon material without long-range crystalline order. Amorphous carbon layers are typically prepared by deposition from a carbon source such as 1-hexene or propylene.

In some embodiments, the protective layer (140) has a thickness of 0.1-1.0 μm, preferably 0.2-0.9 μm, 0.3-0.8 μm, 0.4-0.7 μm, or 0.5 μm. In some embodiments, the protective layer (140) is not included and is optional as will be discussed later. In a preferred embodiment, the protective layer (140) does not impart a significant shape change to the wafer (100). For example, the protective layer (140) does not change a bow of the wafer (100) more than ±20 μm, preferably ±15 μm, ±10 μm, or ±5 μm, relative to the bow of the wafer (100) in the preceding step S30.

Step S50 in FIG. 4A depicts flipping the product produced in step S40 to expose the second surface or back surface of the wafer (100). The second surface also has the thermal oxide layer (110). In this case, the protective layer (140) is now faced downward. In such embodiment, the protective layer (140) can prevent scratching of the first oxide layer (130) while downward facing and supported by a wafer holder. In a preferred embodiment, any scratches or damage that occurs during the flipping process only affect the protective layer (140) and do not penetrate deep enough to affect the first oxide layer (130).

Step S60 in FIG. 4B depicts the formation of a compressive nitride layer (150) on a second surface or back surface of the wafer (100). In a preferred embodiment, the nitride is silicon nitride (SiN). The compressive nitride layer (150) imparts a compressive stress on the second surface of the wafer (100) causing a positive bow of the wafer (100) when the wafer (100) is in a first surface facing up position. In other words, the compressive nitride layer (150) imparts a compressive stress from the bottom of the wafer (100) to offset the stress induced by the first oxide layer (130) on the first surface of the wafer (100). Such positive bow from the compressive nitride layer (150) compensates for additional layers of the oxide and may prevent breakage or bowing outside of a desired range. The amount of bow induced by the compressive nitride layer (150) can also compensate for the stress induced by the formation of the second oxide layer (160) as described below.

Step S70 in FIG. 4B depicts flipping the product produced in step S60 to expose the protective layer (140), or in some embodiments, when the protective layer (140) is not present the first oxide layer (130) would be exposed. The compressive nitride layer (150) is now facing downward. In a preferred embodiment, no damage is incurred on the first oxide layer (130). In a preferred embodiment, if damage occurs in the steps S50, S60, or S70 it only affects the protective layer (140).

Step S80 in FIG. 4C depicts the removal of the protective layer (140). In a preferred embodiment, the removal process is selective for the removal of the protective layer (140) and does not have an effect on layers (130), (120), (110), (100), or (150). In some embodiments, when the protective layer (140) is a nitride the removal process includes a wet clean with an acid such as phosphoric acid.

In some embodiments, when the protective layer (140) is amorphous carbon, the removal process includes an ash process of the amorphous carbon, for example by a reactive ion etch (RIE) using an O₂ plasma. The ash process removes the amorphous carbon layer to expose the first oxide layer (130) and then wet cleaning can be used to touch up the surface. The wet cleaning may be performed with a solvent or an acid, preferably with dilute hydrofluoric acid or sulfuric acid.

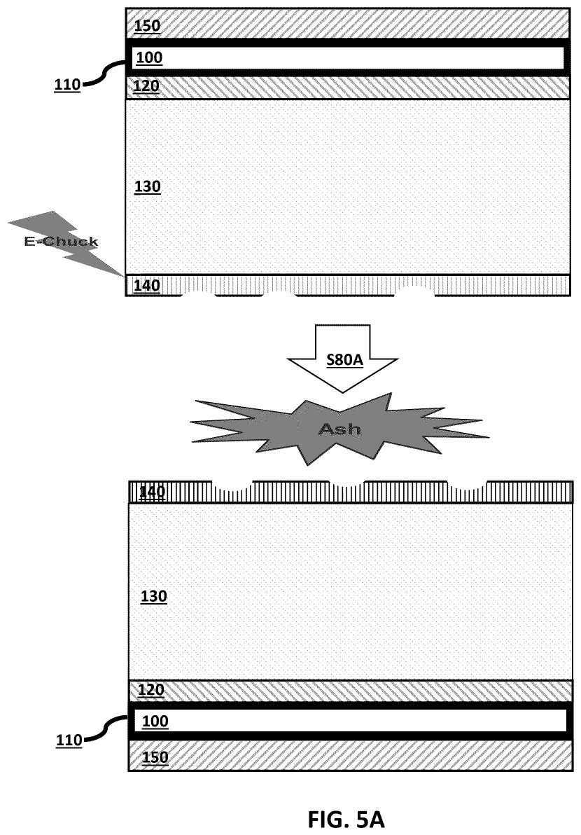

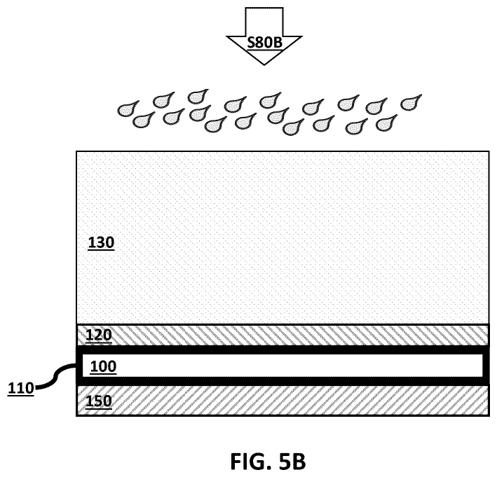

FIGS. 5A and 5B depict a method of removing an amorphous carbon protective layer (140) by step S80A and wet cleaning by step S80B, respectively. In FIG. 5A, initially the protective layer (140) is damaged due to electrostatic chucking of the wafer after flipping. However, the damage does not affect the first oxide layer (130). In step S80A of FIG. 5A, the amorphous carbon is removed by an oxygen ash process, and then in step S80B, a wet clean process is used to remove any small residue left on the surface of the first oxide layer (130), as shown in FIG. 5B.

Following the removal of the protective layer (140) a second oxide layer (160) can be formed in step S90 in FIG. 4C, on top of the first oxide layer (130) to produce a thick oxide layer (170) (the thick oxide layer is a combination of the first and second oxide layers). In some embodiments, a sum of a thickness of the first oxide layer (130) and second oxide layer (160) is greater than or equal to 10 μm, to produce the thick oxide layer (170). In some embodiments, a sum of a thickness of the first oxide layer (130) and second oxide layer (160) is 10-20 μm, preferably 11-19 μm, 12-18 μm, 13-17 μm, 14-16 μm, or 15 μm, to produce the thick oxide layer (170). The formation of the thick oxide layer (170) produces a product wafer (300) which may be used as a SL wafer for developing HAR etch processes for fully integrated devices used in 3D NAND manufacturing.

In some embodiments, the steps of the method in FIGS. 4A-4C can be repeated on the product wafer (300) to further increase a thickness of the thick oxide layer (170). Specifically, the steps S40-S90 can be repeated on the product wafer (300), however, the formation and removal of the protective layer (140) in steps S40 and S80 are not necessary. An overall thickness of the compressive nitride layer (150) formed in step S60 is increased through the deposition of an additional compressive layer to compensate for the additional thickness of the oxide layer formed in the repetition of step S90.

The tensile nitride layer (120), compressive nitride layer (150), and first (130) and second (160) oxide layers may be formed by any method known in the art. The materials in the stacks may be deposited through chemical vapor deposition techniques such as plasma enhanced chemical vapor deposition (PECVD), low pressure chemical vapor deposition (LPCVD), metal organic chemical vapor deposition (MOCVD), atomic layer deposition (ALD), plasma enhanced atomic layer deposition (PEALD), or through direct metal deposition (DMD), etc, or any combination thereof. These examples are not intended to be limiting. In a preferred embodiment, they are formed by PECVD. Different methods of forming the oxide layers may impart different stresses for which the nitride layers will compensate. For example, one processes of depositing the oxide may impart compressive stress on the wafer while another process may impart tensile stress on the wafer. Compressive and/or tensile nitride layers are selectively used to compensate for such stresses of the oxide layer(s).

After each step of the methods described above, the bow of the wafer (100) can be measured. A bow measurement device can be configured to measure a substrate or a wafer (e.g., the unprocessed wafer and the product wafer) to identify a bow measurement of the wafer. In an embodiment, the bow measurement device can use optical (e.g., using a scanning laser technique), acoustic and other mechanisms to measure the z-direction height deviations across a surface of the wafer and store the height deviations by (x, y) coordinates to identify a plurality of sub-bow measurements (x, y) of the bow measurement. The z-direction height deviations can be mapped at various resolutions depending on the type of the metrology equipment used and/or a resolution desired. The bow measurement can include raw bow data or be represented as a bow signature with relative values.

As reported herein the bow values are at room temperature and are relative to the wafer (100) with a first surface facing upwards. In general, tensile stress applied to a first surface of the wafer (100) will bow the wafer (100) up creating a concave shape and a positive bow value. A compressive stress applied to a first surface of the wafer (100) will bow the wafer (100) down creating a convex shape and a negative bow value. However, in some embodiments herein a compressive stress is applied by the compressive nitride layer (150) to a second surface (backside) of the wafer (100), thereby causing the water to bow up creating a concave shape and a positive bow value. Therefore, the tensile nitride layer (120) on the first surface and the compressive nitride layer (150) on the second surface both produce a positive bow value. This synergistically helps in offsetting the negative bow from the stresses of the thick oxide layer (170). In other embodiments, the use of compressive and/or tensile nitride layers on both sides of the wafer can compensate for stress introduced by a thick oxide layer thereby mitigating bowing or warping of the wafer.

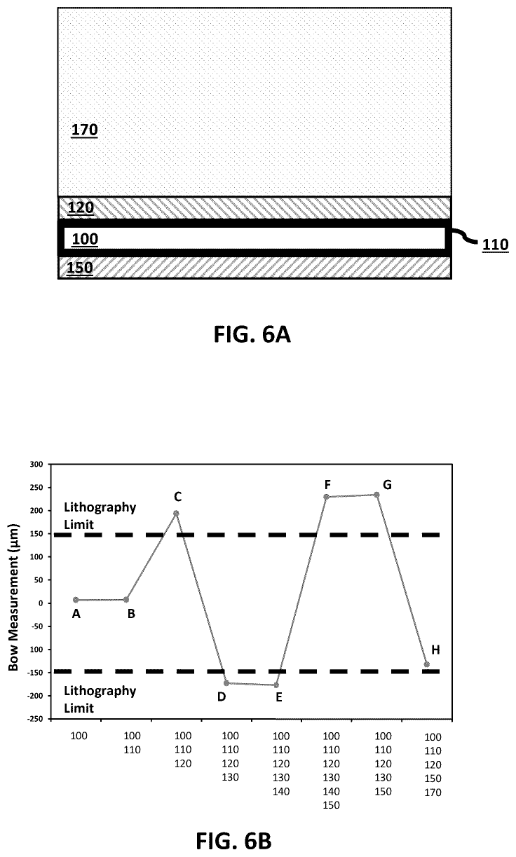

FIG. 6B depicts projected bow values of each step in the methods depicted in FIGS. 2 and 4A-4C. FIG. 6A depicts a product wafer (300) as would be the last bow measurement in FIG. 6B, projected as having a thickness of 16 μm for the thick oxide layer (170). FIG. 6B contains a general range of bow at which lithography can still be reliably performed (±150 μm) noted by the dashed lines. In a preferred embodiment, the bow of the product wafer (300) is within the lithography limit of ±200 μm, preferably ±150 μm, preferably ±100 μm, or preferably ±50 μm. In some cases, the lithography limit can be expanded to ±250 μm. In some embodiments, a bow of the wafer (100) following the forming the second oxide layer (160) is within ±250 μm.

The first data point A in FIG. 6B shows the wafer (100) without any additional layers and is relatively flat, i.e., close to a 0-bow value. The second data point B in FIG. 6B shows that the addition of the thermal oxide layer (110) in step S10 of FIG. 2A, does not have a large effect on the bow of the wafer (100). The third data point C in FIG. 6B shows that the addition of the tensile nitride layer (120) in step S20 of FIG. 2, increases the bow to a positive value outside of the lithography limit as a tensile stress is applied to a first surface of the wafer (100) thereby bowing the wafer (100) up creating a concave shape and a positive bow value. The fourth data point D in FIG. 6B shows that the addition of the first oxide layer (130) in step S30 of FIG. 2, decreases the bow due to compressive stress of the oxide and/or the added weight on top of the wafer (100) and pushes the bow in a negative direction outside of the lithography limit. In this case the first oxide layer (130) has a thickness of less than 10 μm, preferably less than 8 μm, or less than 7 μm, and if it were to have a greater thickness the bow could result in significant deformation or wafer breakage. The compressive nitride layer (150) may be added to the backside of the wafer for additional compensation for the thickness of the oxide layer.

The fifth data point E in FIG. 6B shows that the addition of the protective layer (140) in step S40 of FIG. 4A, does not have a large effect on the bow of the wafer (100) and primarily acts as a sacrificial layer to protect the first oxide layer (130) when the wafer (100) is flipped. The sixth data point F in FIG. 6B shows that the addition of the compressive nitride layer (150) in step S60 of FIG. 4B, increases the bow to a positive value outside of the lithography limit as a compressive stress is applied to a second surface of the wafer (100) thereby bowing the wafer (100) up creating a concave shape and a positive bow value. The seventh data point G in FIG. 6B shows that the removal of the protective layer (140) in step S80 of FIG. 4C, does not have a large effect on the bow of the wafer (100). The eighth data point H in FIG. 6B shows that the addition of the second oxide layer (160) in step S90 of FIG. 4C, decreases the bow due to the further added weight on top of the wafer (100), however, due to the presence of both the tensile nitride layer (120) and the compressive nitride layer (150) which offset the bow in a positive direction, the decrease in bow from the second oxide layer (160) does not push the bow outside of the lithography limit. Therefore, this method allows for the production of a wafer with a thick oxide layer without significant deformation of the wafer.

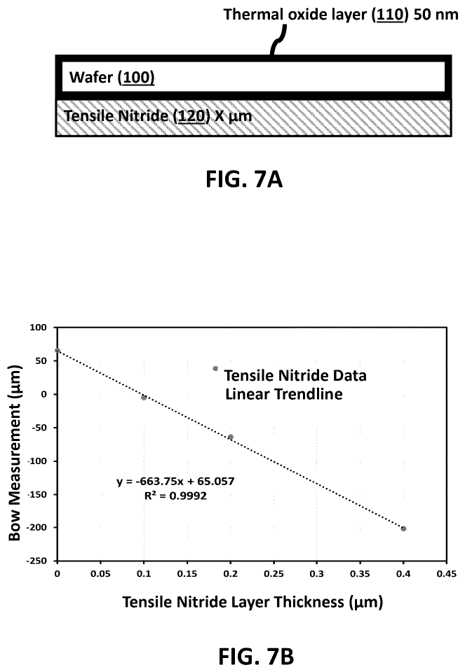

In some embodiments, a thickness of the tensile nitride layer (120) is varied based on a desired thickness of the thick oxide layer (170), i.e., the sum of the thickness of the first oxide layer (130) and the second oxide layer (160). As depicted in FIGS. 7A and 7B differences in a thickness of the tensile nitride layer (120) impart different amounts of stress and bow on the wafer (100). FIG. 7A depicts a wafer having a thermal oxide layer and a tensile nitride layer on a backside. The bow values measured for the backside tensile nitride layer have a opposite sign of a tensile nitride formed on a front side of the wafer. Nonetheless, the addition of a tensile nitride layer produces different amount of stress on the wafer based on the thickness of the tensile nitride layer, and as shown in FIG. 7B, the bow value linearly correlates to the thickness of the tensile nitride layer. A fit of the trendline is shown in the inset of FIG. 7B. Therefore, a thickness of the tensile nitride layer (120) can be adjusted based on the desired offset to the thick oxide layer (170). However, the thickness of the tensile nitride layer (120) cannot be adjusted after the first oxide layer (130) is formed, therefore a desired thickness and offset of the tensile nitride layer (120) is calculated prior to the formation of the tensile nitride layer (120). The tensile stress offset of the tensile nitride layer (120) can be calculated based on the values in the trendline of FIG. 7B. For example, if a bow offset of 100 μm is needed, the value can be input as y in the trendline and then the thickness (x) can be extrapolated. In some embodiments, the tensile nitride layer (120) has a thickness of 0.1-0.4 μm, preferably 0.15-0.35 μm, 0.20-0.30 μm, or about 0.25 μm.

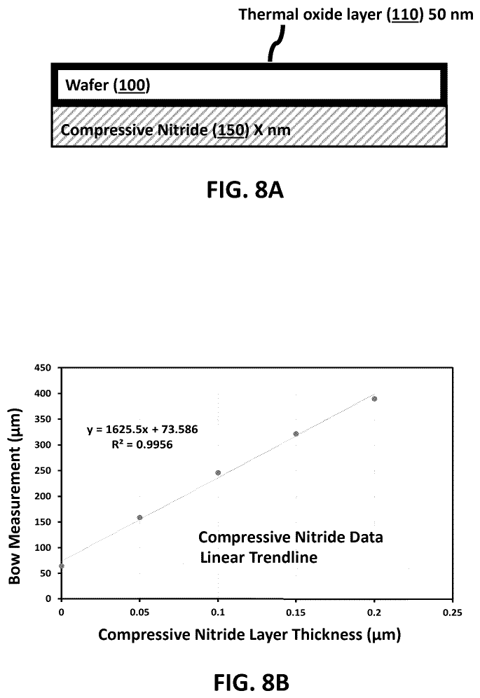

In some embodiments, a thickness of the compressive nitride layer (150) is varied based on a desired thickness of the thick oxide layer (170), i.e., the sum of the thickness of the first oxide layer (130) and the second oxide layer (160). As depicted in FIGS. 8A and 8B differences in a thickness of the compressive nitride layer impart different amounts of stress and bow on the wafer. FIG. 8A depicts a wafer having a thermal oxide layer and a compressive nitride layer on a backside. The addition of a compressive nitride layer produces a different amount of stress on the wafer based on the thickness of the compressive nitride layer, and as shown in FIG. 8B, the bow value linearly correlates to the thickness of the compressive nitride layer. A fit of the trendline is shown in the inset of FIG. 8B. Therefore, a thickness of the compressive nitride layer (150) can be adjusted based on the desired offset to the thick oxide layer (170). However, unlike the tensile nitride layer (120), as there is not another layer on top of the compressive nitride layer (150) the thickness of the compressive nitride layer (150) can be adjusted after the first oxide layer (130) and second oxides layers (160) are formed. Therefore, the thickness of the compressive nitride layer (150) can be also adjusted based on a bow of the wafer (100) following the forming the first oxide layer (130). For example, after the first oxide layer (130) is formed, a bow of the wafer (100) can be measured. Based on the measured bow the amount of the compressive nitride layer (150) to be formed can be calculated and adjusted based on how much offset is needed. The compressive stress offset of the compressive nitride layer (150) can be calculated based on the values in the trendline of FIG. 8B. For example, if a bow offset of 100 μm is needed, the value can be input as y in the trendline and then the thickness (x) can be extrapolated. In some embodiments, the compressive nitride layer (150) has a thickness of 0.01-1 μm, preferably 0.05-0.9 μm, 0.1-0.8 μm, 0.2-0.7 μm, 0.3-0.6 μm, or 0.4-0.5 μm.

In some embodiments, the compressive nitride layer (150) imparts a larger relative stress per thickness on the wafer (100) than the tensile nitride layer (120). In some embodiments, the tensile nitride layer (120) has a larger thickness than the compressive nitride layer (150). In some embodiments, the compressive nitride layer (150) has a larger thickness than the tensile nitride layer (120).

The data presented is derived from standard semiconductor metrology equipment common to the industry. Laser interferometry is a technique that can be used to measure the warp or bow of a wafer. The basic principle behind this technique is that it measures the changes in the wavelength of light that is reflected off the surface of the wafer. In laser interferometry, a laser beam is split into two separate beams using a beam splitter. One beam is directed at the wafer while the other beam is directed at a reference mirror. Both beams are then reflected back to the beam splitter, where they recombine. When the two beams recombine, they create an interference pattern, which can be detected using a photodetector. This interference pattern will be affected by the bowing or warping of the wafer. Specifically, if the wafer is warped, then the reflected light waves will have traveled slightly different distances, resulting in a shift in the interference pattern. By analyzing the interference pattern, laser interferometry can measure the degree of warping in the wafer.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “wafer” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

The substrate can be any suitable substrate, such as a silicon (Si) substrate, a germanium (Ge) substrate, a silicon-germanium (SiGe) substrate, and/or a silicon-on-insulator (SOI) substrate. The substrate may include a semiconductor material, for example, a Group IV semiconductor, a Group III-V compound semiconductor, or a Group II-VI oxide semiconductor. The Group IV semiconductor may include Si, Ge, or SiGe. The substrate may be a bulk wafer or an epitaxial layer.

Silicon-containing reactants to form the oxide layers with SiO₂ may include, but are not limited to, silanes, halosilanes, and aminosilanes. A silane contains hydrogen and/or carbon groups, but does not contain a halogen. Examples of silanes are silane, disilane, and organo silanes such as methyl silane, ethyl silane, isopropylsilane, t-butylsilane, dimethylsilane, diethyl silane, di-t-butylsilane, allylsilane, sec-butylsilane, t-hexylsilane, isoamylsilane, t-butyldisilane, di-t-butyldisilane, and the like. A halosilane contains at least one halogen group and may or may not contain hydrogens and/or carbon groups. Examples of halosilanes are iodosilanes, bromosilanes, chlorosilanes and fluorosilanes. Although halosilanes, particularly fluorosilanes, may form reactive halide species that can etch silicon materials, in certain embodiments described herein, the silicon-containing reactant is not present when a plasma is struck. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, t-hexyldimethylchlorosilane, and the like. An aminosilane includes at least one nitrogen atom bonded to a silicon atom, but may also contain hydrogens, oxygens, halogens and carbons. Examples of aminosilanes are mono-, di-, tri- and tetra-aminosilane, as well as substituted mono-, di-, tri- and tetra-aminosilanes, for example, t-butylaminosilane, methylaminosilane, tert-butylsilanamine, bis(tertiarybutylamino)silane (BTBAS), tert-butyl silylcarbamate, and the like. A further example of an aminosilane is trisilylamine. Other potential silicon-containing reactants include tetraethyl orthosilicate (TEOS), and cyclic and non-cyclic TEOS variants such as tetramethoxysilane (TMOS), fluorotriethoxysilane (FTES), Trimethylsilane (TMS), octamethyltetracyclosiloxane (OMCTS), tetramethylcyclotetrasiloxane (TMCTSO), dimethyldimethoxysilane (DMDS), hexamethyldisilazane (HMDS), hexamethyldisiloxane (HMDSO), hexamethylcyclotrisiloxane (HMCTSO), dimethyldiethoxysilane (DMDEOS), methyltrimethoxysilane (MTMOS), tetramethyldisiloxane (TMDSO), divinyltetramethyldisiloxane (VSI2), methyltriethoxysilane (MTEOS), dimethyltetramethoxydisiloxane (DMTMODSO), ethyltriethoxysilane (ETEOS), ethyltrimethoxysilane (ETMOS), hexamethoxydisilane (HMODS), bis(triehtoxysilyl)ethane (BTEOSE), bis(trimethoxysilyl)ethane (BTMOSE), dimethylethoxysilane (DMEOS), tetraethoxydimethyldisiloxane (TEODMDSO), tetrakis(trimehtylsiloxy)silane (TTMSOS), tetramethyldiethoxydisiloxane (TMDEODSO), triethoxysilane (TIEOS), trimethoxysilane (TIMEOS), or tetrapropoxysilane (TPOS).

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method, comprising:
forming a thermal oxide layer on a first surface and a second surface of a semiconductor wafer;
forming a tensile nitride layer on the first surface of the semiconductor wafer on top of the thermal oxide layer;
forming a first oxide layer on top of the tensile nitride layer;
forming a compressive nitride layer on the second surface of the semiconductor wafer on top of the thermal oxide layer; and
forming a second oxide layer on top of the first oxide layer,
wherein a sum of a thickness of the first oxide layer and the second oxide layer is greater than or equal to 10 μm.

2. The method of claim 1, further comprising forming a protective layer on top of the first oxide layer before the forming the compressive nitride layer.

3. The method of claim 2, further comprising removing the protective layer on top of the first oxide layer after the forming the compressive nitride layer and before the forming the second oxide layer.

4. The method of claim 2, wherein the protective layer comprises amorphous carbon or a nitride.

5. The method of claim 2, wherein the protective layer has a thickness of 0.1-1 μm.

6. The method of claim 1, wherein the thermal oxide layer has a thickness of 10-100 nm.

7. The method of claim 1, wherein the sum of the thickness of the first oxide layer and second oxide layer is from 10-20 μm.

8. The method of claim 1, further comprising flipping the semiconductor wafer after the forming the first oxide layer in order to expose the second surface onto which the compressive nitride layer is formed.

9. The method of claim 8, further comprising flipping the semiconductor wafer after the forming the compressive nitride layer in order to expose the first oxide layer.

10. The method of claim 1, wherein a bow of the semiconductor wafer following the forming the second oxide layer is within ±250 μm.

11. The method of claim 1, wherein a thickness of the tensile nitride layer is chosen based on a desired thickness of the first oxide layer and the second oxide layer,
wherein the tensile nitride layer imparts a tensile stress on the first surface of the semiconductor wafer to compensate for the desired thickness of the first oxide layer and the second oxide layer.

12. The method of claim 11, wherein the thickness of the tensile nitride layer is chosen by calculating a tensile stress offset of the tensile nitride layer.

13. The method of claim 1, wherein a thickness of the compressive nitride layer is adjusted based on a bow of the semiconductor wafer following the forming the first oxide layer and a desired thickness of the first oxide layer and the second oxide layer,
wherein the compressive nitride layer imparts a compressive stress on the second surface of the semiconductor wafer to compensate for the desired thickness of the first oxide layer and the second oxide layer.

14. The method of claim 13, wherein the thickness of the compressive nitride layer is chosen by calculating a compressive stress offset of the compressive nitride layer.

15. The method of claim 1, wherein the tensile nitride layer has a larger thickness than the compressive nitride layer.

16. The method of claim 1, wherein the method is repeated by forming an additional compressive nitride layer and forming an additional oxide layer until a desired total oxide layer thickness is achieved.

17. The method of claim 1, wherein the tensile nitride layer and the compressive nitride layer impart a positive bow on the semiconductor wafer to offset a negative bow from the first oxide layer and the second oxide layer.

18. A method, comprising:
forming a thermal oxide layer on a first surface and a second surface of a semiconductor wafer;
forming a first nitride layer having one of a tensile stress and a compressive stress on the first surface of the semiconductor wafer;
forming a first oxide layer on top of the first nitride layer;
forming a second nitride layer on the second surface of the semiconductor wafer, the second nitride layer having the other of a tensile stress and a compressive stress; and
forming a second oxide layer on top of the first oxide layer,
wherein a sum of a thickness of the first oxide layer and the second oxide layer is greater than or equal to 10 μm.

19. The method of claim 18, further comprising forming a protective layer on top of the first oxide layer before the forming the second nitride layer.

20. The method of claim 19, further comprising removing the protective layer on top of the first oxide layer after the forming the second nitride layer and before the forming the second oxide layer.
